(19) United States
(12) Patent Application Publication
(10) Pub. No.: US 2008/0042715 A1
(43) Pub. Date: Feb. 21, 2008

(54) Delay circuit

(75) Inventors: Wen-Wann Sheen, Taipei County (TW); Ming-Hsin Chan, Xizhi City (TW)

Correspondence Address: BIRCH STEWART KOLASCH & BIRCH, PO BOX 747, FALLS CHURCH, VA, 22040-0747, US

(73) Assignee: Princeton Technology Corporation

(21) Appl. No.: 11/729,801

(22) Filed: Mar. 30, 2007

(30) Foreign Application Priority Data
Jul. 25, 2006 (TW) 095127091

(51) Int. Cl. H03H 11/26

(52) U.S. Cl. 327/284

(57) ABSTRACT

A delay circuit comprises a first inverter, a resistor, a first capacitor and a second capacitor. The first inverter comprises an input end and a first node and an input signal is received by the input end. The resistor is coupled between the first node and a second node. The first capacitor is coupled between the second node and a voltage source. The second capacitor is coupled between the second node and a ground.

### BACKGROUND OF THE INVENTION

1. Field of the Invention

The invention relates to a delay circuit, and more particularly to a delay circuit possible of compensating the effects of process and voltage variation.

2. Description of the Related Art

FIG. 1 is a schematic view of conventional delay circuit 100. Conventional delay circuit 100 comprises inverter 120 and 130, resistor 106 and capacitor 108.

Inverter 120 is coupled between input terminal IN and node N1. Resistor 106 is coupled between node N1 and node N2. Capacitor 108 is an NMOS transistor, a gate of the NMOS transistor is coupled to node N2 and a body of the NMOS transistor is coupled to ground GND. Inverter 130 is coupled between node N2 and output terminal OUT.

Inverter 120 comprises transistor 102 and 104. Transistor 102 has a source coupled to voltage source VDD, a drain coupled to node N1 and a gate. Transistor 104 has a drain coupled to node N1, a source coupled to ground GND and a gate. The gates of transistor 102 and 104 are coupled in common to input terminal IN for receiving an input signal. Note that, transistor 102 is a PMOS transistor and transistor 104 is an NMOS transistor.

Inverter 130 comprises transistors 110 and 112. Transistor 110 has a source coupled to voltage source VDD, a drain coupled to output terminal OUT and a gate. Transistor 112 has a drain coupled to output terminal OUT, a source coupled to ground GND and a gate. The gates of transistor 110 and 112 are common coupled to node N2.

In conventional delay circuit 100, transistor 102 and 104 are used as resistors (referred to as a MOS resistor), capacitor 108 is a MOS capacitor, and resistor 106 is a Hi-R resistor. Characteristic MOS resistor, MOS capacitor and Hi-R resistor MOS resistor are however influenced by process variation of 10%, 10% and 20% drift respectively. The MOS resistor (transistor 102 and 104) is in inverse proportion to the voltage square.

The variation range of parameters of a transistor is defined according to the range of the characteristic drift of the transistor. Three parameters are defined for NMOS and PMOS respectively (S: slow, T: typical, F: fast). NMOS and PMOS may bias to one of the three parameters. FIG. 2 shows the possible combinations of the three parameters S, T and F with respect to the process variation, FF, FS, SF, SS and TT respectively. The former parameter stands for the characteristic parameter of the NMOS transistor, and the latter stands for the characteristic parameter of the PMOS transistor. For example, FS represents that the characteristic parameter of the NMOS is F and the characteristic parameter of the PMOS is S.

When the threshold voltage Vth of the MOS is lower, the gate oxide of the MOS is thinner, such that the current and the capacitance may be increased. At this time the characteristic parameter of the MOS is F. When the threshold voltage Vth of the MOS is higher, the gate oxide of the MOS is thicker, such that the current and the capacitance may be decreased. At this time the characteristic parameter of the MOS is S.

Take the characteristic parameter biased to FS for example, that is, the characteristic parameter of the NMOS F and the characteristic parameter of the PMOS is S. Transistor 104 turns on and transistor 102 turns off when the input at input terminal IN is 1, such that capacitor 108 discharges by transistor 104 through resistor 106. Capacitance of capacitor 108 implemented by the NMOS transistor increases with respect to process variation, because the characteristic parameter of the NMOS is F. When the characteristic parameter of the NMOS transistor is F the threshold voltage Vth of the NMOS is decreased, and the resistance of transistor 104 decreases with respect to the voltage square. The RC latency may be increased when the capacitance of capacitor 108 and the resistance of resistor 104 increases.

Take the characteristic parameter biased to SF for example, that is, the characteristic parameter of the NMOS is S and the characteristic parameter of the PMOS is F. Transistor 104 turns on and transistor 102 turns off when the input at input terminal IN is 1, such that capacitor 108 discharges by transistor 104 through resistor 106. Capacitance of capacitor 108 implemented by the NMOS transistor decreases with respect to the process variation, since the characteristic parameter of the NMOS is S. In addition, when the characteristic parameter of the NMOS transistor is S representing that the threshold voltage Vth of the NMOS is increased, and the resistance of transistor 104 increases with respect to the voltage square. The RC latency may be decreased when the capacitance of capacitor 108 and the resistance of resistor 104 increases.

Because the delay circuit of FIG. 1 is affected by different process variations a larger RC delay range may result. A delay circuit possible of compensating effects of the process variation and voltage is required, since the RC delay influenced by the process variation and voltage may affect normal operation of other circuits.

### BRIEF SUMMARY OF INVENTION

Delay circuits are provided. An exemplary embodiment of a delay circuit comprises a first inverter having an input terminal and a first node, the input terminal is used to receive an input signal, a resistor coupled between the first node and a second node, a first capacitor coupled between the second node and a voltage source, and a second capacitor coupled between the second node and a ground.

Another exemplary embodiment of a delay circuit comprises a first inverter having an input terminal and a first node, the input terminal is used to receive an input signal, a resistor coupled between the first node and a second node, a first capacitor set comprising a plurality of capacitors -connected in series, having a first terminal coupled to a voltage source, and a second terminal coupled to the second node, and a second capacitor set comprising a plurality of capacitors connected in series, having a third terminal coupled to the second node, and a fourth terminal coupled to a ground.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a schematic view of a conventional delay circuit.

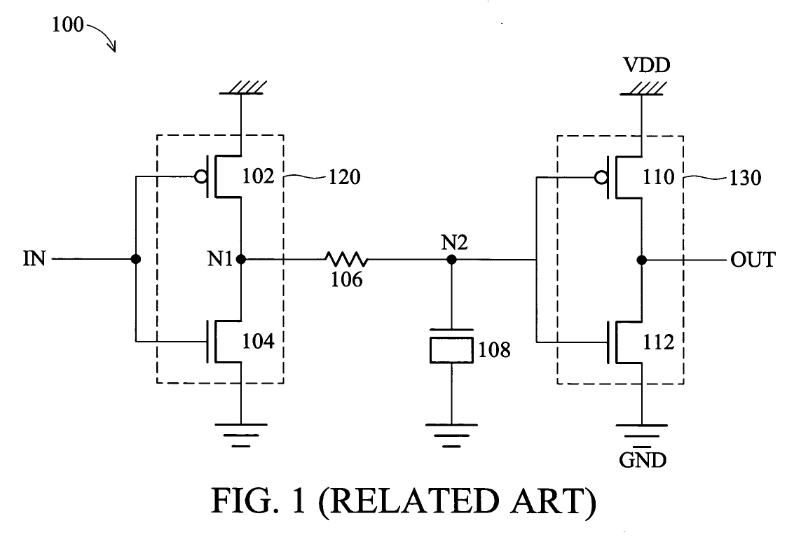

FIG. 2 shows all possible combinations of an NMOS and a PMOS with respect to the process variation, FF, FS, SF, SS and TT respectively, the former stands for the characteristic parameter of the NMOS and the latter stands for the characteristic parameter of the PMOS.

FIG. 3 is a schematic view of a delay circuit according to an embodiment of the invention.

FIG. 4 shows the characteristics between MOS capacitors and voltages.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

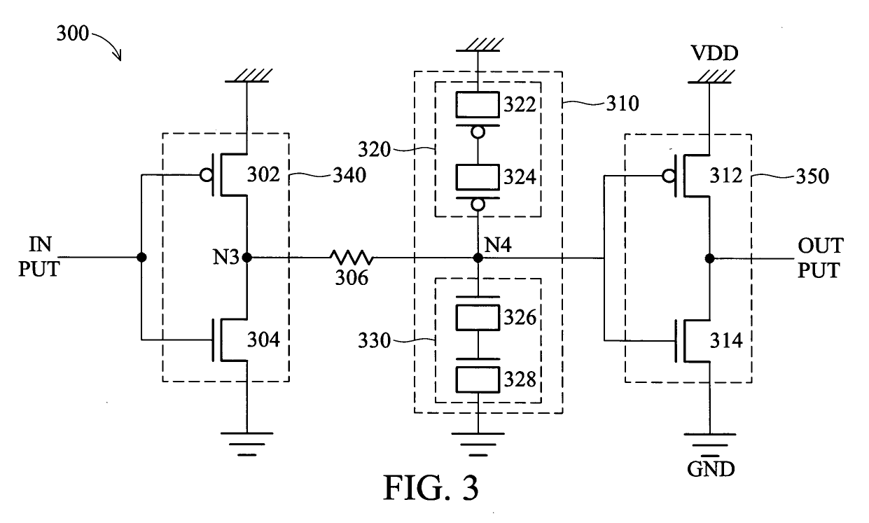

FIG. 3 is a delay circuit 300 according to an embodiment of the invention. Delay circuit 300 comprises first inverter 340, resistor 306, a set of capacitors 310 and second inverter 350.

First inverter 340 is coupled between input terminal INPUT and first node N3. Resistor 306 is coupled between first node N3 and second node N4. The set of capacitors 310 is coupled between voltage source VDD and ground GND. Second inverter 350 is coupled between second node N4 and output terminal OUTPUT.

First inverter 340 comprises first transistor 302 and second transistor 304. First transistor 302 has a first first terminal coupled to voltage source VDD, a first second terminal coupled to first node N3 and a first gate. Second transistor 304 has a second first terminal coupled to first node N3, a second second terminal coupled to ground GND and a second gate. The gate of the first gate and the second gate are coupled in common to input terminal INPUT for receiving an input signal. Note that, first transistor 302 is a PMOS transistor and second transistor 304 is an NMOS transistor.

Second inverter 350 comprises third transistor 312 and fourth transistor 314. Third transistor 312 has a third first gate coupled to voltage source VDD, a third second gate coupled to output terminal OUTPUT and a third gate. Fourth transistor 314 has a fourth first terminal coupled to output terminal OUTPUT, a fourth second terminal coupled to ground GND and a fourth gate. The third gate and the fourth gate are coupled in common to second node N4.

The set of capacitors 310 comprises first capacitor set 320 and second capacitor set 330. First capacitor set is coupled in parallel to second capacitor set 330 at second node N4.

First capacitor set 320 comprises two capacitors 322 and 324 connected in series, wherein MOS capacitor 322 and 324 is implemented by PMOS transistor. The base of MOS capacitor 322 is coupled to voltage source VDD, the gate of MOS capacitor 322 is coupled to the base of MOS capacitor 423, and the gate of MOS capacitor 324 is coupled to second node N4.

Second capacitor set 330 comprises two MOS capacitor 326 and 328, wherein MOS capacitor 326 and 328 is implemented by NMOS transistor. The base of MOS capacitor 328 is coupled to ground GND, the gate of MOS capacitor 328 is coupled to the base of MOS capacitor 326, and the gate of MOS capacitor 326 is coupled to second node N4.

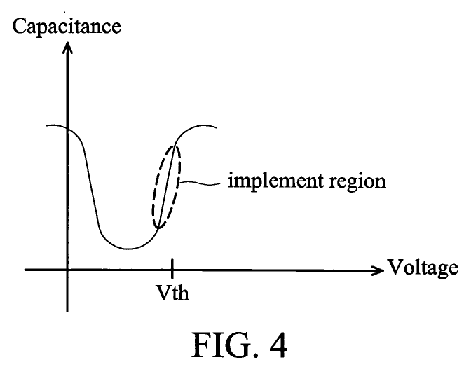

FIG. 4 illustrates the characteristics of the MOS capacitor with respect to voltage. The characteristic of a capacitor is that the voltage of the MOS capacitor is about linear to the operating voltage when the operating voltage is within the threshold voltage Vth. In this invention, the RC delay influenced by the process and voltage variation is compensated by the characteristics of the MOS capacitor.

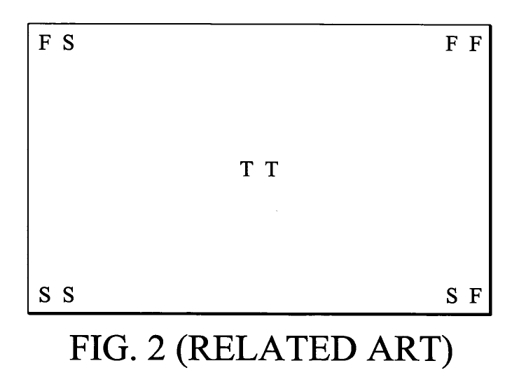

The variation range of parameters of a transistor is defined according to the range of the characteristic drift of the transistor. Three parameters are defined for NMOS and PMOS respectively (S: slow, T: typical, F: fast). NMOS and PMOS may bias to one of the three parameters. FIG. 2 shows the possible combinations of the three parameters S, T and F with respect to the process variation, FF, FS, SF, SS and TT respectively, the former parameter stands for the characteristic parameter of the NMOS transistor, and the latter stands for the characteristic parameter of the PMOS transistor. For example, FS represents the characteristic parameter of the NMOS as F and the characteristic parameter of the PMOS as S.

When the threshold voltage Vth of the MOS is lower, the gate oxide of the MOS is thinner, such that the current and the capacitance may be increased, at this time the characteristic parameter of the MOS is F. When the threshold voltage Vth of the MOS is higher, the gate oxide of the MOS is thicker, such that the current and the capacitance may be decreased, at this time the characteristic parameter of the MOS is S.

Take the characteristic parameter biased to FS for example, that is the characteristic parameter of the NMOS is F and the characteristic parameter of the PMOS is S. Transistor 304 turns on and transistor 302 turns off when the input at input terminal INPUT is 1, such that capacitor set 310 is discharged by transistor 304 through resistor 306. Capacitance of the MOS capacitors 326 and 328 implemented by the NMOS transistor increases with respect to process variation, because the characteristic parameter of the NMOS is F. Additionally, capacitance of the MOS capacitors 322 and 324 implemented by the PMOS transistor decreases with respect to the process variation, since the characteristic parameter of the PMOS is S. Therefore, the total capacitance of capacitor group 310 is the sum of serial capacitance of MOS capacitors 322 and 324 in parallel with the serial capacitance of MOS capacitors 326 and 328. In addition, when the characteristic parameter of the NMOS transistor is F representing that the threshold voltage Vth of the NMOS is decreased, and the resistance of transistor 304 decreases with respect to the voltage square, and the capacitance and voltage increase linearly (the capacitance is in proportion to the voltage) because the operating voltage is near the threshold voltage Vth. The offset in the RC delay of the invention is smaller than that of conventional delay circuit 100, since the RC delay is compensated by the MOS capacitors 322 and 324.

Take the characteristic parameter biased to SF for example, that is the characteristic parameter of the NMOS is S and the characteristic parameter of the PMOS is F. Transistor 304 turns on and transistor 302 turns off when the input at input terminal INPUT is 1, such that capacitor set 310 is discharged by transistor 304 through resistor 306. The capacitance of the MOS capacitors 326 and 328 implemented by the NMOS transistor may be decreased with respect to the process variation, since the characteristic parameter of the NMOS is S. Therefore, the total capacitance of capacitor group 310 is the sum of serial capacitance of MOS capacitors 322 and 324 in parallel with the serial capacitance of MOS capacitors 326 and 328. In addition, capacitance of the MOS capacitor 322 and 324 implemented by the PMOS transistor may be increased with respect to process variation, because the characteristic parameter of the PMOS is F. In addition, when the characteristic parameter of the NMOS transistor is S representing that the threshold voltage Vth of the NMOS is increased, and the resistance of transistor 304 increases with respect to the voltage square, and the capacitance and voltage is decreased linearly (the capacitance is in inverse proportion to the voltage) because the operating voltage is near the threshold voltage Vth. The offset in the RC delay of the invention is smaller than that of conventional delay circuit 100, since the RC delay is compensated by the MOS capacitors 322 and 324.

The invention is not limited to the two described embodiments (the characteristic parameter of MOS in discharging mode biased to FS to SF). The offset of the RC delay influenced by the process and voltage variation may be decreased, since the RC delay may be compensated by the delay circuit disclosed in the invention when the characteristic parameter of MOS in charging or discharging mode is biased to FF, FS, SF, or SS.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A delay circuit, comprising:
a first inverter having an input terminal and a first node, the input terminal is used to receive an input signal;
a resistor coupled between the first node and a second node;
a first capacitor coupled between the second node and a voltage source; and
a second capacitor coupled between the second node and a ground.

2. The delay circuit as claimed in claim 1, further comprising a second inverter coupled between an output terminal and the second node.

3. The delay circuit as claimed in claim 1, wherein the first inverter comprises a first transistor and a second transistor.

4. The delay circuit as claimed in claim 3, wherein the first transistor has a first first terminal coupled to the voltage source, a first second terminal coupled to the first node, and a first gate coupled to the input terminal, and the second transistor has a second first terminal coupled to the first node, a second second terminal coupled to the ground, and a second gate coupled to the input terminal.

5. The delay circuit as claimed in claim 3, wherein the first transistor is a PMOS transistor, and the second transistor is an NMOS transistor.

6. The delay circuit as claimed in claim 1, wherein the first capacitor and the second capacitor are implemented by transistors.

7. The delay circuit as claimed in claim 6, wherein the first capacitor is a PMOS transistor, a base of the first capacitor is coupled to the voltage source, and the a gate of the first capacitor is coupled to the second node.

8. The delay circuit as claimed in claim 7, wherein the second capacitor is an NMOS transistor, a base of the second capacitor is coupled to the ground, and a gate of the second capacitor is coupled to the second node.

9. The delay circuit as claimed in claim 2, wherein the second inverter comprises a third transistor and a fourth transistor.

10. The delay circuit as claimed in claim 9, wherein the third transistor has a third first gate coupled to the voltage source, a third second gate coupled to the output terminal, and a third gate coupled to the second node, and the fourth transistor has a fourth first terminal coupled to the output terminal, a fourth second terminal coupled to the ground, and a fourth gate coupled to the second node.

11. The delay circuit as claimed in claim 9, wherein the third transistor is a PMOS transistor, and the fourth transistor is an NMOS transistor.

12. A delay circuit, comprising:
a first inverter having an input terminal and a first node, the input terminal is used to receive an input signal;
a resistor coupled between the first node and a second node;
a first capacitor set comprising a plurality of capacitors connected in series, having a first terminal coupled to a voltage source, and a second terminal coupled to the second node; and
a second capacitor set comprising a plurality of capacitors connected in series, having a third terminal coupled to the second node, and a fourth terminal coupled to a ground.

13. The delay circuit as claimed in claim 12, further comprising a second inverter coupled between an output terminal and the second node.

14. The delay circuit as claimed in claim 12, wherein the first inverter comprises a first transistor and a second transistor.

15. The delay circuit as claimed in claim 14, wherein the first transistor has a first first terminal coupled to the voltage source, a first second terminal coupled to the first node, and a first gate coupled to the input terminal, and the second transistor has a second first terminal coupled to the first node, a second second terminal coupled to the ground, and a second gate coupled to the input terminal.

16. The delay circuit as claimed in claim 14, wherein the first transistor is a PMOS transistor and the second transistor is an NMOS transistor.

17. The delay circuit as claimed in claim 12, wherein capacitors in the first capacitor set and the second capacitor set are implemented by transistors.

18. The delay circuit as claimed in claim 17, wherein the first capacitor set comprises a plurality of PMOS transistors connected in series, a base of one of the PMOS transistors is coupled to the first terminal, and a gate of the other of the PMOS transistors is coupled to the second terminal.

19. The delay circuit as claimed in claim 18, wherein the second capacitor set comprises a plurality of NMOS transistors connected in series, a base of one of the NMOS transistors is coupled to the fourth terminal, and a gate of the other of the NMOS transistors is coupled to the third terminal.

20. The delay circuit as claimed in claim 13, wherein the second inverter comprises a third transistor and a fourth transistor.

21. The delay circuit as claimed in claim 20, wherein the third transistor has a third first terminal coupled to the voltage source, a third second terminal coupled to the output terminal, and a third gate coupled to the second node, and the fourth transistor has a fourth first terminal coupled to the output terminal, a fourth second terminal coupled to the ground, and a fourth gate coupled to the second node.

22. The delay circuit as claimed in claim 20, wherein the third transistor is a PMOS transistor and the fourth transistor is an NMOS transistor.
